(19) United States
(12) Patent Application Publication
(10) Pub. No.: US 2007/0126349 A1
(43) Pub. Date: Jun. 7, 2007

(54) Dual emission display

(75) Inventor: Min-Chieh Hu, Tainan Hsien (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/478,654

(22) Filed: Jul. 3, 2006

(30) Foreign Application Priority Data
Dec. 2, 2005 (TW) 94142597

(51) Int. Cl. H01L 51/00

(52) U.S. Cl. 313/506

(57) ABSTRACT

A dual emission display includes a substrate whose upper surface has a first organic light emitting diode, and whose lower surface has a second organic light emitting diode. The first organic light emitting diode and the second organic light emitting diode are respectively covered by a first protecting layer and a second protecting layer to isolate moisture and oxygen.

This application claims the benefit of Taiwan Patent Application Serial No. 094142597, filed Dec. 2, 2005, the subject matter of which is incorporated herein by reference.

### BACKGROUND OF THE INVENTION

(1) Field of the Invention

The present invention relates to a dual emission display, more particularly, to a dual emission display having organic light emitting diodes mounted on two surfaces of the same one substrate.

(2) Description of the Prior Art

As the electric products are getting more and more various, they emphasize two display screens. For example, a mobile phone having a dual emission display can display a main function menu at one side, and display time at the other side. Typically, the dual emission display includes two adhered single-side panels, such as a liquid crystal panel adhered to an organic electro-luminescent panel, two adhered liquid crystal panels, or two adhered organic electro-luminescent panels.

FIG. 1 shows a dual emission display according to the prior art. The dual emission display 10 includes a first display panel 11 and a second display panel 12. The first display panel 11 has a transparent substrate 111, a first electrode 112, an light emitting layer 113, a second electrode 114 and a package lid 115. The light emitting layer 113 is disposed between the first electrode 112 and the second electrode 114. The first electrode 112 is formed on the transparent substrate 111. The package lid 115 is adhered to the transparent panel 111. The second display panel 12 has a transparent substrate 121, a third electrode 122, an light emitting layer 123, a forth electrode 124 and a package lid 125. The light emitting layer 123 is disposed between the third electrode 122 and the forth electrode 124. The third electrode 122 is formed on the transparent panel 121. The package lid 125 is adhered to the transparent substrate 121. The package lid 115 is adhered to the package lid 125 to construct the dual emission display 10.

As stated above, the dual emission display 10 has two package lids 115 and 125, and two transparent substrates 111 and 121. Therefore, it becomes larger, thicker, and heavier, so as not to meet the requirement in weight, thickness and size. Besides, the two display panels 11 and 12 are respectively manufactured in two different processes. Therefore, the fabrication of the dual emission display 10 is complicated and time-consuming. Another drawback is that the two display panels 11 and 12 need to be driven independently.

It is difficult to reduce the thickness because the typical dual emitting device has more complicated manufacturing process and more package lids and substrates.

### SUMMARY OF THE INVENTION

The first object of the present invention is to provide a dual emission display, on different sides of which there are light emitting areas with the same size or not, and elements in alignment with each other or not.

The second object of the present invention is to provide a thinner dual emission display adapted to simpler fabricating process.

Accordingly, the dual emission display includes a substrate whose upper surface has a first organic light emitting diode, and whose lower surface has a second organic light emitting diode. The first organic light emitting diode and the second organic light emitting diode are respectively covered with a first protecting layer and a second protecting layer to isolate moisture and oxygen.

The organic light emitting diodes on lower or upper surfaces of the substrate are connected to an image controller through a conductive wire, so as to display images on two sides of the dual emission display independently. The structure of the dual emission display may be fabricated by evaporating on two sides of the substrate simultaneously, or in different stages. Therefore, the light emitting areas on different sides of the dual emission display are not limited to the same size, but arranged with light emitting elements independently. The result structure is thinner than the typical dual emission display, and is adapted to simpler fabricating process.

### BRIEF DESCRIPTION OF THE DRAWINGS

The present invention will now be specified with reference to its preferred embodiment illustrated in the drawings, in which

FIG. 1 is an dual emission display according to the prior art;

FIG. 2 is an first embodiment of the dual emission display according to the present invention; and

FIG. 3 is the second embodiment of the dual emission display according to the present invention.

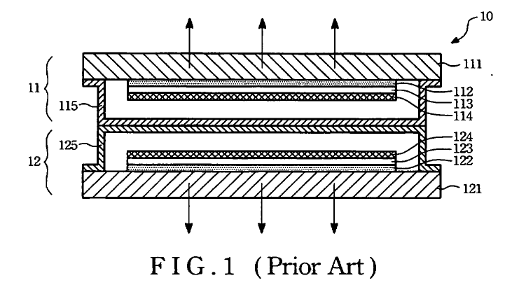

### DESCRIPTION OF THE PREFERRED EMBODIMENT

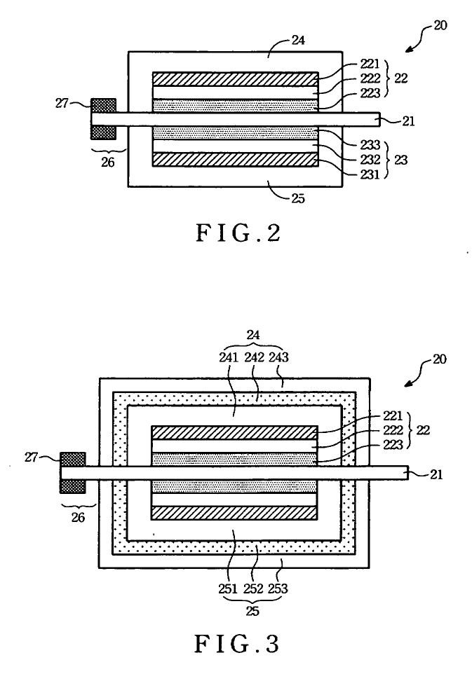

FIG. 2 shows the first embodiment of the present invention. The dual emission display 20 includes a substrate 21, two organic light emitting diodes 22 and 23 respectively disposed on the upper and lower surfaces of the substrate 21, two protecting layers 24 and 25 covering on the organic light emitting diodes 22 and 23 to isolate moisture and oxygen. Both the upper and lower surfaces of the substrate 21 have bonding zones 26 outside the protecting layers 24 and 25 to electrically connect to an image controller 27.

The protecting layer 24 may include one single layer or a plurality of sub-layers. The sub-layers include at least one inorganic material, such as aluminum oxide, silicon nitride, silicon oxide, silicon carbonate and diamond-like carbon etc. Preferably, the protecting layer 24 includes a complex structure consisting of a polymer film 241, a silicon oxygen film 242 and a silicon nitride film 243. Likewise, the protecting layer 25 may be a single-layer or multi-layer structure, and made of the same materials as or different materials from the protecting layer 24. The protecting layers 24 and 25 require 30 percent or above of light transmission to cover the light exit surface of the dual emission display 20.

The bonding zone 26 has bonding pads or conductive wires (not shown) to electrically connect to image controllers 27 such as scan drivers, data drivers or to bond with flexible printed circuits (FPCS, not shown). The elements on the upper and lower surfaces of the substrate 21 may be controlled by the same image controller 27, or different image controllers 27. Therefore, the dual emission display 20 can display the same images or different images simultaneously on its two sides.

FIG. 3 is the second embodiment of the present invention. The protecting layer 24 or 25 of dual emission display 20 may be a complex structure of polymer layer 241 or 251, oxide layer 242 or 252, nitride layer 243 or 253, and bonding zone 26. The polymer layers 241 and 251 are disposed on and below the transparent substrate 21 to cover the organic light emitting diodes 22 and 23, respectively. The oxide layers 242 and 252, such as silicon oxide etc., cover the polymer layers 241 and 251, respectively. The nitride layers 243 and 253, such as silicon nitride etc., cover the oxide layers 242 and 252, respectively. The bonding zones 26 are disposed on the surfaces of nitride layers 243 and 253.

The fabricating process of the second embodiment is described in detail. The reflective electrode 223, the organic emission layer 222 and the transparent electrode 221 are formed on the upper surface of transparent substrate 21 to construct the organic light emitting diode 22. The reflective electrode 233, the organic emission layer 232 and the transparent electrode 231 are formed on the lower surface of the transparent substrate 21 to construct the organic light emitting diode 23. The polymer layers 241 and 251 are formed on the transparent electrodes 221 and 231 of the organic light emitting diodes 22 and 23, respectively. The oxide layers 242 and 252 are evaporated on the polymer layers 241 and 251. The nitride layers 243 and 252 are evaporated on the oxide layers 242 and 252. The image controller 27 is connected to the substrate 21 via a conductive wire. Each above-mentioned layer can be formed by screen printing or organic vapor phase deposition (OVPD). In addition, it is available to evaporate at two sides of the substrate 21 simultaneously.

Above organic light emitting light diode can be a polymer organic light emitting diode (Polymer OLED) or a small molecular organic light emitting diode (SMOLED) which feature in electroluminescent. The reflective electrodes 223 and 233 can be metal electrodes formed on the substrate 21, so the light is reflected not to enter the substrate 21. The reflective electrode and the transparent electrode are not limited to be anode or cathode. By the way, the reflective electrodes 223 and 233 are interposed with a deep color or black insulating layer or replaced with a black electrode, or added with anti-reflective or light-absorbing materials for improving the anti-reflective ability and avoiding the leakage of light.

A hole or electron passing area is placed between the electrodes and the light emitting layer. In the hole passing area, a hole injecting layer (not shown) or a hole transporting layer (not shown) is interposed selectively. In the electron passing area, an electron injecting layer (not shown) or an electron transporting layer (not shown) is interposed selectively.

The electron transporting layer may be made of (8-hydroxyquinolinolato) aluminum (Alq), 1,3,5-Tris (N-phenylbenzimidazol-2-yl)benzene(TPBI), derivatives of anthracene, or derivatives of fluorine, spirofluorine etc., mixed with n-type dopant such as alkali halides, alkaline-earth halides, alkali oxides or metal-carbonate compound etc. to increase electron mobility thereof.

The electron injecting layer may be made of metal compound with work function perfectly adapted to that of the non-transparent electrode, such as alkali halides, alkaline-earth halides, alkali oxides or metal-carbonate compound, or an organic layer mixed with such n-type dopants.

The hole transporting layer may be made of allylamine group material such as N,N-di(naphthalene-1-yl)-N,N-diphenyl-benzidene (NPB).

The hole injecting layer may be made of allylamine group material, or phthalocyanine group material such as CuP.

The transparent electrode may be made of metal or transparent conductive materials such as ITO, IZO etc. The transparent substrate may be made of glass or plastic. The dual emission displays description in the present invention can be combined with the drivers such as thin film transistors, so they can be formed as active or passive displays.

In comparison with the prior art, the present invention has advantages of fewer substrates, more flexible arrangement of light emitters, thinner panel, simpler fabricating process and preferred moisture and oxygen resistance.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A dual emission display comprising:
a substrate;
a first organic light emitting diode disposed on the upper surface of the substrate;
a second organic light emitting diode disposed on the lower surface of the substrate;
a first protecting layer covering the first organic light emitting diode; and
a second protecting layer covering the second organic light emitting diode.

2. The dual emission display of claim 1, wherein both the upper and lower surfaces of the substrate include a bonding zone outside the first and second protecting layers to electrically connect to a first and second image controllers, respectively.

3. The dual emission display of claim 1, wherein the first protecting layer includes a plurality of sub-layers.

4. The dual emission display of claim 1, wherein the first protecting layer includes at least one sub-layer made of inorganic material.

5. The dual emission display of claim 4, wherein the inorganic material is selected from the group consisting of aluminum oxide, silicon nitride, silicon oxide, silicon carbonate, and diamond-like carbon.

6. The dual emission display of claim 1, wherein the first protecting layer includes a complex structure consisting of a polymer, a silicon oxygen, and a silicon nitride.

7. The dual emission display of claim 1, wherein the second protecting layer includes a plurality of sub-layers.

8. The dual emission display of claim 1, wherein the second protecting layer includes at least one sub-layer made of inorganic material.

9. The dual emission display of claim 8, wherein the inorganic material is selected from the group consisting of aluminum oxide, silicon nitride, silicon oxide, silicon carbonate, and diamond-like carbon.

10. The dual emission display of claim 1, wherein the second protecting layer includes a complex structure consisting of a polymer film, a silicon oxygen film and a silicon nitride film.

11. The dual emission display of claim 1, wherein the first protecting layer has a light transmissivity equal to or more than 30 percent.

12. The dual emission display of claim 1, wherein the second protecting layer has a light transmissivity equal to or more than 30 percent.

13. The dual emission display of claim 1, wherein at least one of the first and second organic light emitting diodes is a polymer electroluminescent diode.

14. The dual emission display of claim 1, wherein at least one of the first and second organic light emitting diodes is a small molecular electroluminescent diode.

15. A dual emission display comprising:
a substrate;
a first organic light emitting diode having a reflective electrode disposed on the upper surface of the substrate;
a second organic light emitting diode having a reflective electrode disposed on the lower surface of the substrate;
a first and second polymer layers, the first polymer layer being disposed on a first side of the substrate, the second polymer layer being disposed on a second side of the substrate, to cover the first and second organic light emitting diodes, respectively;
a first and second oxide layers, the first oxide layer being disposed on the first side of the substrate, the second oxide layer being disposed on the second side of the substrate, to cover the first and second polymer layers, respectively;
a first and second nitride layers, the first nitride layer being disposed on the first side of the substrate, the second nitride layer being disposed on the second side of the substrate, to cover the first and second oxide layers respectively; and
a first and second bonding zones, the first bond zone located on the first side of the substrate, the second bonding zone located on the second side of the substrate, outside the first and the second nitride layers, respectively.
